(19) United States
(12) Patent Application Publication
(10) Pub. No.: US 2006/0128038 A1
(43) Pub. Date: Jun. 15, 2006

(54) Method and system for providing a highly textured magnetoresistance element and magnetic memory

(76) Inventors: Mahendra Pakala, Fremont, CA (US); Thierry Valet, Sunnyvale, CA (US); Yiming Huai, Pleasanton, CA (US); Zhitao Diao, Fremont, CA (US)

Correspondence Address: SAWYER LAW GROUP LLP, P O BOX 51418, PALO ALTO, CA, 94303, US

(21) Appl. No.: 11/294,766

(22) Filed: Dec. 5, 2005

Related U.S. Application Data
(60) Provisional application No. 60/634,013, filed on Dec. 6, 2004.

(51) Int. Cl. H01L 21/00

(52) U.S. Cl. 438/4

(57) ABSTRACT

A method and system for providing a magnetic element are disclosed. The method and system include providing a pinned layer, a free layer, and a spacer layer between the pinned layer and the free layer. The spacer layer is insulating and has an ordered crystal structure. The spacer layer is also configured to allow tunneling through the spacer layer. In one aspect, the free layer is comprised of a single magnetic layer having a particular crystal structure and texture with respect to the spacer layer. In another aspect, the free layer is comprised of two sublayers, the first sublayer having a particular crystal structure and texture with respect to the spacer layer and the second sublayer having a lower moment. In still another aspect, the method and system also include providing a second pinned layer and a second spacer layer that is nonmagnetic and resides between the free layer and the second pinned layer. The magnetic element is configured to allow the free layer to be switched due to spin transfer when a write current is passed through the magnetic element.

### CROSS-REFERENCE TO RELATED APPLICATION

This application is claiming under 35 USC 119(e), the benefit of provisional patent application Ser. No. 60/634,013 filed on Dec. 6, 2004.

### FIELD OF THE INVENTION

The present invention relates to magnetic memory systems, and more particularly to a method and system for providing a magnetic element having an improved signal and that can be switched using a spin transfer effect at a lower switching current.

### BACKGROUND OF THE INVENTION

FIGS. 1A and 1B depict conventional magnetic elements 10 and 10′. Such conventional magnetic elements 10/10′ can be used in non-volatile memories, such as magnetic random access memories (MRAM). The conventional magnetic element 10 is a spin valve and includes a conventional antiferromagnetic (AFM) layer 12, a conventional pinned layer 14, a conventional nonmagnetic spacer layer 16 and a conventional free layer 18. Other layers (not shown), such as seed or capping layer may also be used. The conventional pinned layer 14 and the conventional free layer 18 are ferromagnetic. Thus, the conventional free layer 18 is depicted as having a changeable magnetization 19. The conventional nonmagnetic spacer layer 16 is conductive. The AFM layer 12 is used to fix, or pin, the magnetization of the pinned layer 14 in a particular direction. The magnetization of the free layer 18 is free to rotate, typically in response to an external magnetic field. The conventional magnetic element 10′ depicted in FIG. 1B is a spin tunneling junction. Portions of the conventional spin tunneling junction 10′ are analogous to the conventional spin valve 10. However, the conventional barrier layer 16′ is an insulator that is thin enough for electrons to tunnel through in a conventional spin tunneling junction 10′.

Depending upon the orientations of the magnetization 19/19′ of the conventional free layer 18/18′ and the conventional pinned layer 14/14′, respectively, the resistance of the conventional magnetic element 10/10′, respectively, changes. When the magnetization 19/19′ of the conventional free layer 18/18′ is parallel to the magnetization of the conventional pinned layer 14/14′, the resistance of the conventional magnetic element 10/10′ is low. When the magnetization 19/19′ of the conventional free layer 18/18′ is antiparallel to the magnetization of the conventional pinned layer 14/14′, the resistance of the conventional magnetic element 10/10′ is high.

To sense the resistance of the conventional magnetic element 10/10′, current is driven through the conventional magnetic element 10/10′. Typically in memory applications, current is driven in a CPP (current perpendicular to the plane) configuration, perpendicular to the layers of conventional magnetic element 10/10′ (up or down, in the z-direction as seen in FIG. 1A or 1B). Based upon the change in resistance, typically measured using the magnitude of the voltage drop across the conventional magnetic element 10/10′, the resistance state and, therefore, the data stored in the conventional magnetic element 10/10′ can be determined.

It has been proposed that particular materials be used to increase the magnitude of the difference in resistance between the high and low resistance states of the conventional magnetic element 10′. In particular, it has been proposed that epitaxial or highly textured Fe or Co be used for the pinned layer 14′ and free layer 18′ and epitaxial or highly textured MgO be used for the conventional barrier layer 16′. For such structures, a large magnetoresistance, up to several hundred percent difference between the high and low resistance states, can be achieved.

Spin transfer is an effect that may be utilized to switch the magnetizations 19/19′ of the conventional free layers 18/18′, thereby storing data in the conventional magnetic elements 10/10′. Spin transfer is described in the context of the conventional magnetic element 10′, but is equally applicable to the conventional magnetic element 10. The following description of the spin transfer phenomenon is based upon current knowledge and is not intended to limit the scope of the invention.

When a spin-polarized current traverses a magnetic multilayer such as the spin tunneling junction 10′ in a CPP configuration, a portion of the spin angular momentum of electrons incident on a ferromagnetic layer may be transferred to the ferromagnetic layer. Electrons incident on the conventional free layer 18′ may transfer a portion of their spin angular momentum to the conventional free layer 18′. As a result, a spin-polarized current can switch the magnetization 19′ direction of the conventional free layer 18′ if the current density is sufficiently high (approximately 10⁷-10⁸ A/cm²) and the lateral dimensions of the spin tunneling junction are small (approximately less than two hundred nanometers). In addition, for spin transfer to be able to switch the magnetization 19′ direction of the conventional free layer 18′, the conventional free layer 18′ should be sufficiently thin, for instance, generally less than approximately ten nanometers for Co. Spin transfer based switching of magnetization dominates over other switching mechanisms and becomes observable when the lateral dimensions of the conventional magnetic element 10/10′ are small, in the range of few hundred nanometers. Consequently, spin transfer is suitable for higher density magnetic memories having smaller magnetic elements 10/10′.

Spin transfer can be used in the CPP configuration as an alternative to or in addition to using an external switching field to switch the direction of magnetization of the conventional free layer 18′ of the conventional spin tunneling junction 10′. For example, the magnetization 19′ of the conventional free layer 18′ can be switched from antiparallel to the magnetization of the conventional pinned layer 14′ to parallel to the magnetization of the conventional pinned layer 14′. Current is driven from the conventional free layer 18′ to the conventional pinned layer 14′ (conduction electrons traveling from the conventional pinned layer 14′ to the conventional free layer 18′). The majority electrons traveling from the conventional pinned layer 14′ have their spins polarized in the same direction as the magnetization of the conventional pinned layer 14′. These electrons may transfer a sufficient portion of their angular momentum to the conventional free layer 18′ to switch the magnetization 19′ of the conventional free layer 18′ to be parallel to that of the conventional pinned layer 14′. Alternatively, the magnetization of the free layer 18′ can be switched from a direction parallel to the magnetization of the conventional pinned layer 14′ to antiparallel to the magnetization of the conventional pinned layer 14′. When current is driven from the conventional pinned layer 14′ to the conventional free layer 18′ (conduction electrons traveling in the opposite direction), majority electrons have their spins polarized in the direction of magnetization of the conventional free layer 18′. These majority electrons are transmitted by the conventional pinned layer 14′. The minority electrons are reflected from the conventional pinned layer 14′, return to the conventional free layer 18′ and may transfer a sufficient amount of their angular momentum to switch the magnetization 19′ of the free layer 18′ antiparallel to that of the conventional pinned layer 14′.

Although spin transfer can be used in switching the magnetization 19/19′ of the conventional free layer 18/18′, one of ordinary skill in the art will readily recognize that a high current density is typically required. In particular, the current required to switch the magnetization 19/19′ is termed the critical current. As discussed above, the critical current corresponds to a critical current density that is approximately at least 10⁷ A/cm². One of ordinary skill in the art will also readily recognize that such a high current density implies that a high write current and a small magnetic element size are necessary.

Use of a high critical current for switching the magnetization 19/19′ adversely affects the utility and reliability of such conventional magnetic elements 10/10′ in a magnetic memory. The high critical current corresponds to a high write current. The use of a high write current is associated with increased power consumption, which is undesirable. The high write current may require that larger structures, such as isolation transistors, be used with the conventional magnetic element 10/10′ to form memory cells. Consequently, the areal density of such a memory is reduced. In addition, the conventional magnetic element 10′, which has a higher resistance and thus a higher signal, may be less reliable because the conventional barrier layer 16′ may be subject to dielectric breakdown at higher write currents. Thus, even though a higher signal read may be achieved, the conventional magnetic elements 10/10′ may be unsuitable for use in higher density conventional MRAMs using spin transfer to write to the conventional magnetic elements 10/10′.

Accordingly, what is needed is a system and method for providing a magnetic memory element that can be switched using spin transfer at a lower write current. The present invention addresses such a need.

### BRIEF SUMMARY OF THE INVENTION

The present invention provides a method and system for providing a magnetic element. The method and system comprise providing a pinned layer, a free layer, and a spacer layer between the pinned layer and the free layer. The spacer layer is insulating and has an ordered crystal structure. The spacer layer is also configured to allow tunneling through the spacer layer. In one aspect, the method and system also comprise providing a second pinned layer and a second spacer layer that is nonmagnetic, either conductive or insulating, and resides between the free layer and the second pinned layer. The magnetic element is configured to allow the free layer to be switched due to spin transfer when a write current is passed through the magnetic element

According to the method and system disclosed herein, the present invention provides a magnetic element having a higher signal and that can be written using spin transfer at a lower write current.

### BRIEF DESCRIPTION OF SEVERAL VIEWS OF THE DRAWINGS

FIG. 1A is a diagram of a conventional magnetic element, a spin valve.

FIG. 1B is a diagram of another conventional magnetic element, a spin tunneling junction.

FIG. 2 is a diagram of a recently developed dual spin filter that can be written using spin transfer.

FIG. 3 is a diagram of a first embodiment of a magnetic element in accordance with the present invention and which can be written using spin transfer.

FIG. 4 is a more detailed diagram of the first embodiment of a magnetic element in accordance with the present invention and which can be written using spin transfer.

FIG. 5 is a diagram of a second version of the first embodiment of a magnetic element in accordance with the present invention and which can be written using spin transfer.

FIG. 6 is a diagram of a third version of the first embodiment of a magnetic element in accordance with the present invention and which can be written using spin transfer.

FIG. 7 is a diagram of a second embodiment of a magnetic element in accordance with the present invention and which can be written using spin transfer.

FIG. 8 is a diagram of a second version of the second embodiment of a magnetic element in accordance with the present invention and which can be written using spin transfer.

FIG. 9 is a diagram depicting one embodiment of a method in accordance with the present invention for providing magnetic element in accordance which can be written using spin transfer.

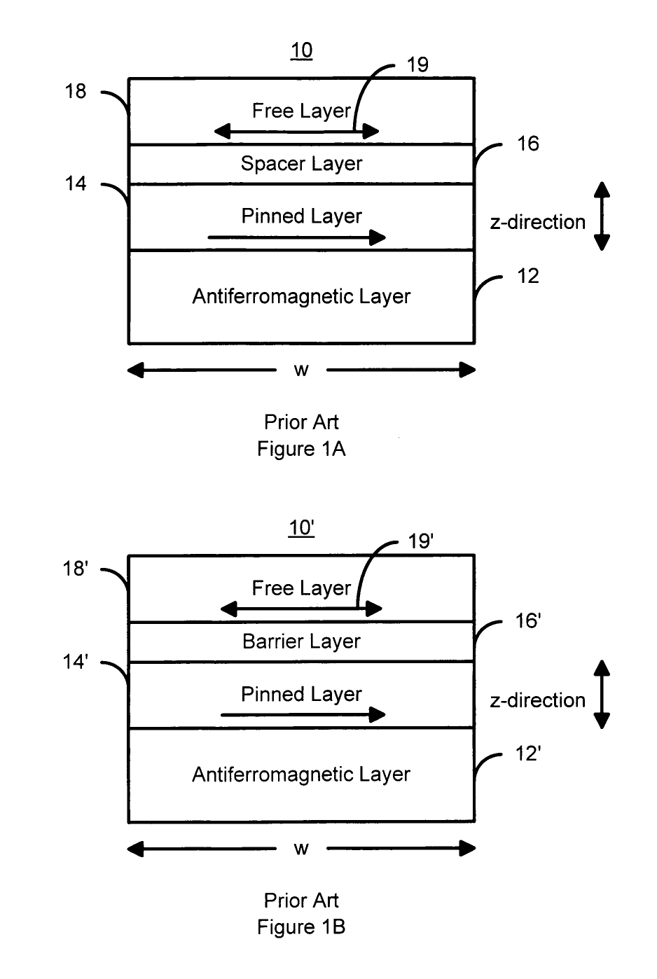

### DETAILED DESCRIPTION OF THE INVENTION

The present invention relates to magnetic elements and magnetic memories such as MRAM. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

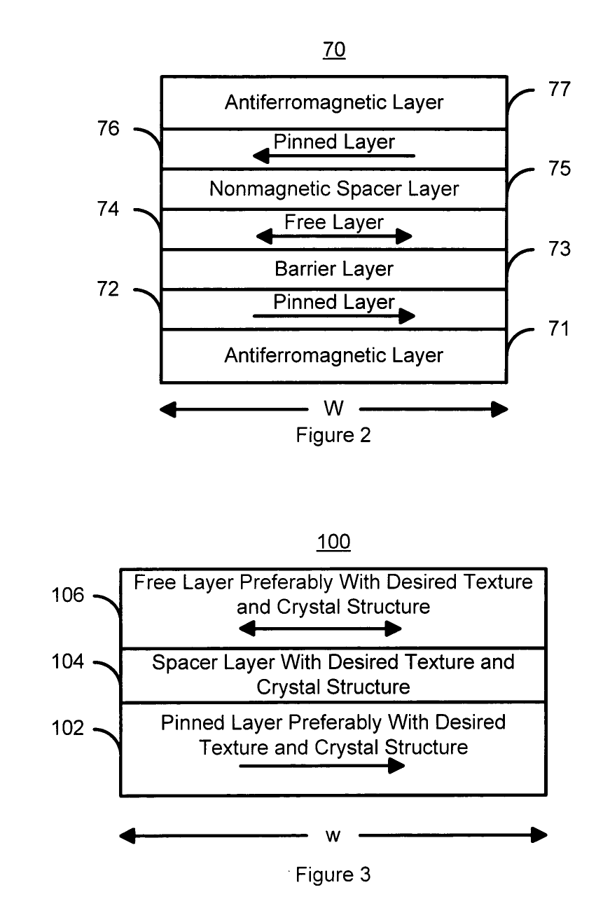

FIG. 2 is a diagram of one embodiment of a magnetic element termed a dual spin filter 70 that can be used as a magnetic element. The dual spin filter 70 is preferably fabricated upon the appropriate seed layer. The dual spin filter 70 includes an antiferromagnetic (AFM) layer 71 upon which a pinned layer 72 is fabricated. The pinned layer 72 is ferromagnetic and has its magnetization pinned by the AFM layer 71. The dual spin filter 70 also includes a first spacer layer 73. The first spacer layer 73 may be a barrier layer 73 that is insulating and is thin enough to allow charge carriers to tunnel between the pinned layer 72 and the free layer 74. Alternatively, the first spacer layer 73 may be a current confined layer including conductive channels (not specifically shown) residing in an insulating matrix (not explicitly shown). In such a structure, conduction of current between the pinned layer 72 and the free layer 74 is confined in the conductive channels. The free layer 74 is ferromagnetic and has a magnetization that can be changed due to the spin transfer phenomenon. The dual spin filter 70 also includes a nonmagnetic spacer layer 75 that is conductive and can include materials such as Cu. The dual spin filter 70 includes a second pinned layer 76 that is ferromagnetic and has a magnetization that is pinned by the AFM layer 77. The dual spin filter 70 can be considered to be made up of a spin tunneling junction or current confined junction (including layers 71, 72, 73 and 74) and a spin valve (including layers 74, 75, 76, and 77), which share a free layer 74. Consequently, a higher read signal can be achieved while allowing writing using spin transfer. Although described as single ferromagnetic films, the layers 72, 74 and 76 may be synthetic, and/or may be doped to improve the thermal stability of the dual spin filter 70. In addition, other magnetic elements having free layers that are magnetostatically coupled, including dual spin filters, having magnetostatically coupled free layers have been described. Consequently, other structures using magnetic elements such as spin tunneling junctions or dual spin filters can also be provided.

The dual spin filter 70 is configured to allow the magnetization of the free layer 74 to be switched using spin transfer. Consequently, the dimensions of the dual spin filter 70 are preferably small, in the range of few hundred nanometers to reduce the self field effect. In a preferred embodiment, the dimensions of the dual spin filter 70 are less than two hundred nanometers and preferably approximately one hundred nanometers. The dual spin filter 70 preferably has a depth, perpendicular to the plane of the page in FIG. 2, of approximately fifty nanometers. The depth is preferably smaller than the width of the dual spin filter 70 so that the dual spin filter 70 has some shape anisotropy, ensuring that the free layer 74 has a preferred direction. In addition, the thickness of the free layer 74 is low enough so that the spin transfer is strong enough to rotate the free layer magnetization into alignment with the magnetizations of the pinned layers 72 and 76. In a preferred embodiment, the free layer 74 has a thickness of less than or equal to 10 nm. In addition, for a dual spin filter 70 having the preferred dimensions, a sufficient current density on the order of 10⁷ Amps/cm² can be provided at a relatively small current. For example, a current density of approximately 10⁷ Amps/cm² can be provided with a current of approximately 0.5 mA for a dual spin filter 70 having an ellipsoidal shape of 0.06×0.12 μm². As a result, the use of special circuitry for delivering very high currents may be avoided.

Thus, use of the dual spin filter 70 allows for the use of spin transfer as a switching mechanism and an improved signal. Moreover, the dual spin filter 70 may be fabricated such that it possesses a relatively low areal resistance. For example, areal resistances of below thirty Ohm-μm² may be achieved. Further, the magnetization of the free layer 74 may be kept relatively low, allowing the critical current for the dual spin filter 70 to be reduced.

Although the magnetic element 70 discussed above may function well for its intended purpose, one of ordinary skill in the art will also recognize that it is desirable to reduce the critical current required to switch the magnetic element 70. It would also be desirable to increase the signal from the magnetic element 70.

The present invention provides a method and system for providing a magnetic element. The method and system comprise providing a pinned layer, a free layer, and a spacer layer between the pinned layer and the free layer. The spacer layer is insulating and has an ordered crystal structure. The spacer layer is also configured to allow tunneling through the spacer layer. In one aspect, the method and system also comprise providing a second pinned layer and a second spacer layer that is nonmagnetic, conductive and resides between the free layer and the second pinned layer. The magnetic element is configured to allow the free layer to be switched due to spin transfer when a write current is passed through the magnetic element.

The present invention will be described in terms of a particular magnetic memory and a particular magnetic element having certain components. However, one of ordinary skill in the art will readily recognize that this method and system will operate effectively for other magnetic memory elements having different and/or additional components and/or other magnetic memories having different and/or other features not inconsistent with the present invention. The present invention is also described in the context of current understanding of the spin transfer phenomenon. Consequently, one of ordinary skill in the art will readily recognize that theoretical explanations of the behavior of the method and system are made based upon this current understanding of spin transfer. One of ordinary skill in the art will also readily recognize that the method and system are described in the context of a structure having a particular relationship to the substrate. However, one of ordinary skill in the art will readily recognize that the method and system are consistent with other structures. In addition, the method and system are described in the context of certain layers being synthetic and/or simple. However, one of ordinary skill in the art will readily recognize that the layers could have another structure. Furthermore, the present invention is described in the context of magnetic elements having particular layers. However, one of ordinary skill in the art will readily recognize that magnetic elements having additional and/or different layers not inconsistent with the present invention could also be used. Moreover, certain components are described as being ferromagnetic. However, as used herein, the term ferromagnetic could include ferrimagnetic or like structures. Thus, as used herein, the term “ferromagnetic” includes, but is not limited to ferromagnets and ferrimagnets. The present invention is also described in the context of single elements. However, one of ordinary skill in the art will readily recognize that the present invention is consistent with the use of magnetic memories having multiple elements, bit lines, and word lines.

FIG. 3 is a high-level diagram of a first embodiment of a magnetic element 100 in accordance with the present invention and which can be written using spin transfer. The magnetic element 100 includes a pinned layer 102, a spacer layer 104, and a free layer 106. In a preferred embodiment, the magnetic element 100 also includes a pinning layer (not shown) that is preferably an AFM layer. Although depicted as a simple layer, the pinned layer 102 may be a synthetic pinned layer including two ferromagnetic layers separated by a nonmagnetic spacer layer. The thickness of the nonmagnetic spacer layer is configured so that the magnetizations of the ferromagnetic layers are antiferromagnetically coupled. In a preferred embodiment, the pinned layer 102, or the ferromagnetic layer adjacent to the spacer layer 104, has a body centered cubic (bcc) structure. In a preferred embodiment, the pinned layer 102, or the ferromagnetic layer adjacent to the spacer layer 104, has a texture. In a preferred embodiment, this texture is (100) for the bcc crystal structure. Thus, for grains within the pinned layer 102, the (100) direction is preferred to be perpendicular to the plane of the layers. Stated differently, a majority of grains in the pinned layer 102 have the (100) direction perpendicular to the plane of the layer. Also in a preferred embodiment, the pinned layer 102, or the ferromagnetic layer adjacent to the spacer layer 104, is a metallic alloy including at least one of Co, Fe, Ni, Cr, and Mn, or an amorphous alloy including at least one of Co, Fe, Ni, and Cr, with at least one of B, P, Si, Nb, Zr, Hf, Ta, Ti, wherein amorphous materials transform to crystal structures with desired texture after post heat treatment and recrystallization.

The spacer layer 104 is insulating. The spacer layer 104 also has an ordered crystal structure. Stated differently, the spacer layer 104 is not amorphous. The spacer layer also preferably has a texture. In a preferred embodiment, there is a well defined relationship between the texture of the pinned layer 102, or the ferromagnetic that is adjacent to the spacer layer 104, and the texture of the spacer layer 104. In a preferred embodiment, the textures are the same. Thus, in a preferred embodiment, the texture of the spacer layer 104 is (100). Also in a preferred embodiment, the spacer layer 104 includes at least ten atomic percent Mg and has a rock salt (NaCl) structure. Thus, the spacer layer 104 is preferably MgO. The spacer layer 104 is also configured to allow tunneling through the spacer layer. Consequently, in a preferred embodiment, the pinned layer 102 is a bcc structure having a (100) orientation, while the spacer layer is preferably MgO having a cubic structure and a (100) orientation.

The free layer 106 is depicted as a simple layer. In such an embodiment, the free layer 106 would preferably have a bcc crystal structure and a texture that preferably has a (100) orientation. In another embodiment, the free layer 106 preferably includes two ferromagnetic sublayers (not separately shown). The first sublayer, closest to spacer layer 104, preferably has a bcc crystal structure and a (100) texture. The second sublayer would preferably have a reduced magnetic moment. The magnetizations of the sublayers would be closely coupled such that the relative orientations of the magnetizations of the sublayers would be constant. The free layer 106 might also include a nonmagnetic spacer layer between the sublayers. In such an embodiment, the magnetizations would remain antiparallel or parallel due to coupling across the nonmagnetic spacer layer. Also in a preferred embodiment, the free layer 106 or its first sublayer is a metallic alloy including at least one of Co, Fe, Ni, Cr, and Mn, or an amorphous alloy including at least one of Co, Fe, Ni, and Cr, with at least one of B, P, Si, Nb, Zr, Hf, Ta, Ti. The second sublayer preferably has the form MX, where M contains at least one of Co, Fe, Ni, Cr and Mn, and X can be elements such as B or Ta, which can help reduce the moment of the free layer or could be Pt or Pd, which helps in decreasing the perpendicular anisotropy.

The magnetic element 100 is also configured to allow the free layer 106 to be switched due to spin transfer when a write current is passed through the magnetic element 100. In a preferred embodiment, the lateral dimensions, such as the width w, of the free layer 106 are thus small and preferably less than two hundred nanometers. In addition, some difference is preferably provided between the lateral dimensions to ensure that the free layer 106 has a particular easy axis.

Thus, the magnetic element 100 can be written using spin transfer. Further, because of the crystal structure of the spacer layer 104 and the relationship between the textures of the spacer layer 104 and the pinned layer 102, well defined electronic states dominate the tunneling process through the spacer layer 104. This is further improved by the texture of the free layer 106. Consequently, the magnetoresistance signal of the magnetic element 100 may be increased. The signal from the magnetic element 100 may, therefore, be increased. Furthermore, the improved spin polarization through the spacer layer 104 is improved. The critical current required to switch the magnetization of the free layer 106 is inversely proportional to the spin transfer efficiency, which is related to spin polarization. Consequently, the critical current required to switch the magnetization of the free layer 106 might be reduced. Thus, the power consumption and ability of the magnetic elements 100 to be used in higher density magnetic memories may be improved.

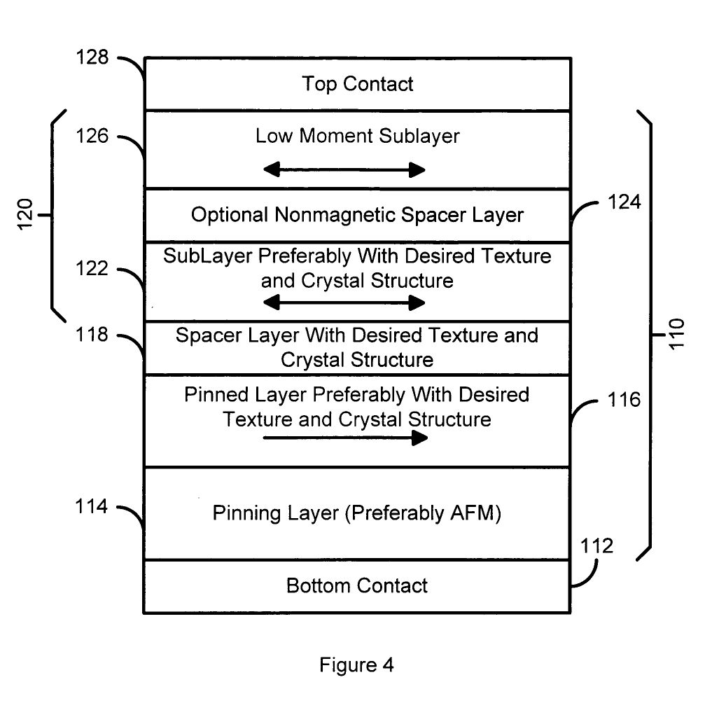

FIG. 4 is a more detailed diagram of a preferred version of the first embodiment of a magnetic element 110 in accordance with the present invention and which can be written using spin transfer. The magnetic element 10 is similar to the magnetic element 100. The magnetic element 110 includes a pinned layer 116, a spacer layer 118, and a free layer 120 that are analogous to the pinned layer 102, the spacer layer 104, and the free layer 106 of the magnetic element 100. The free layer 120 includes a first sublayer 122, an optional nonmagnetic spacer layer 124, and a second sublayer 126.

The magnetic element 110 preferably also includes a pinning layer 114. Also shown are a bottom contact 112 and a top contact 128. The bottom contact 112 and the top contact 128 are used to drive current through the magnetic element 110 in a CPP direction. The pinning layer 114 is preferably an AFM layer. The AFM layer 114 has an ordered crystal structure and, preferably, a particular texture. In addition, seed layers (not shown) may be used to provide a desired texture of the AFM layer 114. For example, if IrMn is used for the AFM layer 114, a Ta(N) underlayer, which is a mixture of β-Ta and TaN, is used to ensure that the IrMn AFM layer 114 is face centered cubic (fcc) having a (002) texture. The AFM layer 114 preferably pins the magnetization of the pinned layer 116 through exchange coupling.

The pinned layer 116 has its magnetization pinned by the pinning layer 114. The portion of the pinned layer 116 adjacent to the spacer layer 118, has a texture. In a preferred embodiment, the portion of the pinned layer adjacent to spacer layer has a bcc crystal structure with a preferred perpendicular texture of (001). Moreover, although depicted as a simple layer, the pinned layer 116 may have another structure. For example, the pinned layer 116 may be a bilayer. In such an embodiment, the layer of the pinned layer 116 that is adjacent to the AFM layer 114 is configured to improve the ability of the AFM layer 114 to pin the magnetization of the pinned layer 116. The other bilayer would be configured to have the texture described above. The pinned layer 116 may be a synthetic pinned layer including two ferromagnetic layers separated by a nonmagnetic spacer layer. The thickness of the nonmagnetic spacer layer is configured so that the magnetizations of the ferromagnetic layers are antiferromagnetically coupled.

The spacer layer 118 is insulating. The spacer layer 118 also has an ordered crystal structure. Stated differently, the spacer layer 118 is not amorphous. The spacer layer also preferably has a texture. In a preferred embodiment, there is a well defined relationship between the texture of the pinned layer 116, or the sublayer of the pinned layer 116 that is adjacent to the spacer layer 118, and the texture of the spacer layer 118. Also in a preferred embodiment, the spacer layer 118 includes at least ten atomic percent Mg and has a rock salt (NaCl) structure. Thus, the spacer layer 118 is preferably MgO. The spacer layer 118 is also configured to allow tunneling through the spacer layer 118. In a preferred embodiment, the texture of the spacer layer 118 is (100).

The free layer 120 preferably includes two ferromagnetic sublayers 122 and 126. The first sublayer 122 preferably has a bcc crystal structure and a (100) texture. Also in a preferred embodiment, the first sublayer is a metallic alloy including at least one of Co, Fe, Ni, Cr, and Mn, or an amorphous alloy including at least one of Co, Fe, Ni, and Cr, with at least one of B, P, Si, Nb, Zr, Hf, Ta, Ti. The second sublayer 126 would preferably have a reduced magnetic moment. A reduced magnetic moment is preferably a magnetic moment of less than or equal to 1100 emu/cm³. In one embodiment, the second sublayer 126 is amorphous, contains more than ten atomic percent of boron, and includes at least one of Co, Fe, Ni, Cr, and Mn. In either case, the sublayers 122 and 126 include Co, Fe or Ni. The magnetizations of the sublayers 122 and 126 are closely coupled such that the relative orientation of the magnetizations of the sublayers 122 and 126 is constant. For example, the magnetizations would remain antiparallel or parallel due to this coupling. The free layer 120 might also include an optional nonmagnetic spacer layer 124 between the sublayers 122 and 126. The optional nonmagnetic spacer layer 124 is preferably configured to exchange couple the magnetizations of the sublayers 122 and 126. In addition, the optional nonmagnetic spacer layer 124 may act as a diffusion stop layer.

The magnetic element 110 is also configured to allow the free layer 120 to be switched due to spin transfer when a write current is passed through the magnetic element 110. In a preferred embodiment, the lateral dimensions, such as the width w, of the free layer 120 are thus small and preferably less than two hundred nanometers. In addition, some difference is preferably provided between the lateral dimensions to ensure that the free layer 120 has a particular easy axis.

Thus, the magnetic element 110 can be written using spin transfer. Further, because of the crystal structure of the spacer layer 118 and the relationship between the textures of the spacer layer 118 and the pinned layer 116, well defined electronic states dominate the tunneling process through the spacer layer 118. This is further improved by the texture of the sublayer 122 of the free layer 120. Consequently, the magnetoresistance signal of the magnetic element 110 may be increased. The signal from the magnetic element 110 may, therefore, be increased. Furthermore, because of the improved conduction of spin polarized current through the spacer layer 118, the critical current required to switch the magnetization of the free layer 120 might be reduced. Thus, the magnetic element 110 may be more readily used in higher density magnetic memories.

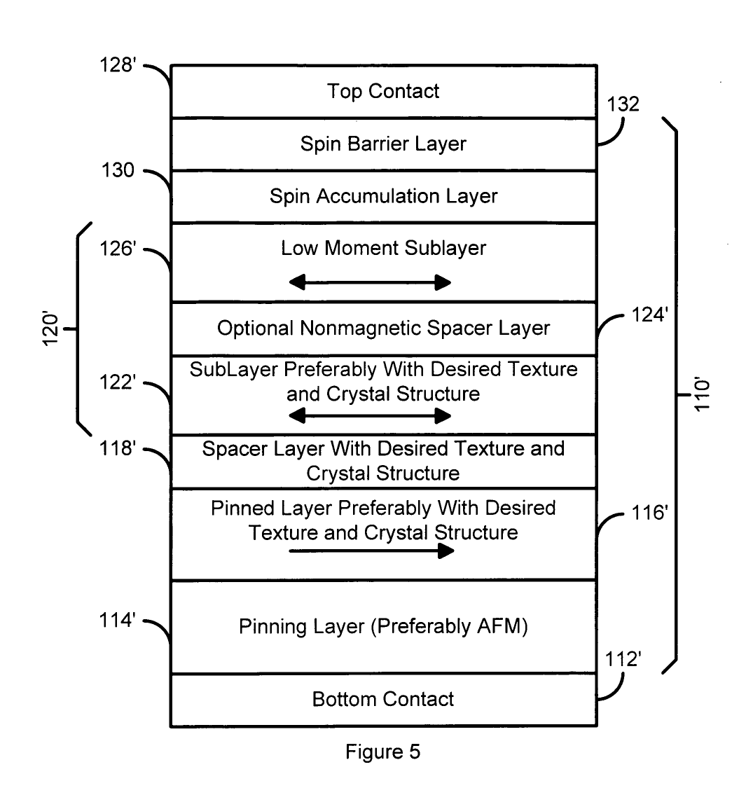

FIG. 5 is a diagram of a second version of the preferred, first embodiment of a magnetic element 110′ in accordance with the present invention and which can be written using spin transfer. The magnetic element 110′ is analogous to the magnetic element 110. Consequently, analogous portions of the magnetic element 110′ are labeled similarly. For example, the magnetic element 110′ includes pinned layer 116′, spacer layer 118′, and free layer 120′ that are analogous to the layers 116, 118, and 120 of the magnetic element 110. Thus, the magnetic element 110′ has the advantages of the magnetic element 110.

In addition, the magnetic element 110′ includes a spin accumulation layer 130 and a spin barrier layer 132. The spin barrier layer 132 is configured to provide specular reflections of electrons, which improves the ability of the free layer 120′ to be switched using spin transfer. For example, the spin barrier layer 132 preferably is a poor tunneling barrier having a low RA product, less than ten percent of the value of the RA of the total magnetic element 110′. Examples of the materials used in the spin barrier layer 132 include oxides of Cu—Al alloys, where the Al is preferentially oxidized.

The spin accumulation layer 130 is a nonmagnetic layer that preferably has a long spin diffusion length, preferably on the order of 20 to 100 A at the least. Thus, the spin accumulation layer 130 preferably includes materials such as Cu and Ru. The spin accumulation layer 130 and the spin barrier layer 132 are used to improve the spin transfer effect's ability to switch the magnetization of the free layer 120′ by reducing additional damping that results from a spin pumping effect. This damping is reduced because the spin accumulation layer 130 and the spin barrier layer 132 can work to reflect current back towards the free layer 120′. Thus, the magnetic element 110′ can be more easily switched, at a lower write current.

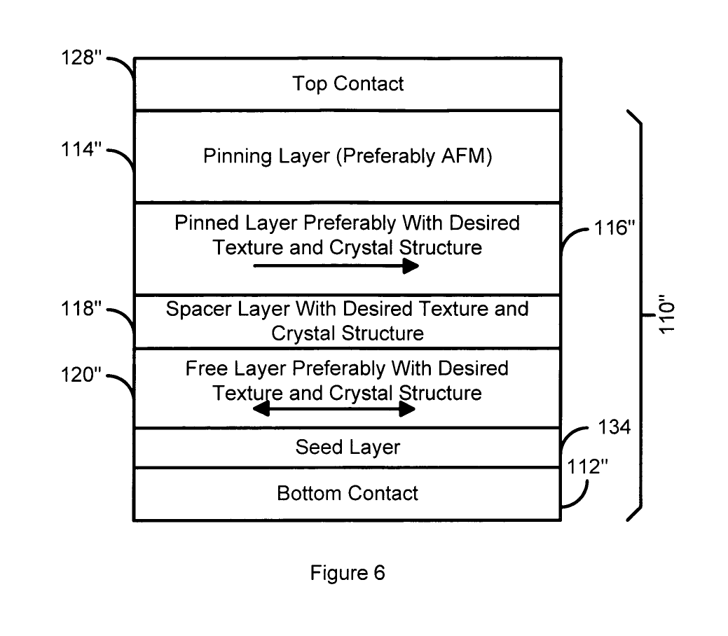

FIG. 6 is a diagram of a third version of the preferred, first embodiment of a magnetic element 110″ in accordance with the present invention and which can be written using spin transfer. The magnetic element 110″ is analogous to the magnetic element 110. Consequently, analogous portions of the magnetic element 110″ are labeled similarly. For example, the magnetic element 110″ includes pinned layer 116″, spacer layer 118″, and free layer 120″ that are analogous to the layers 116, 118, and 120 of the magnetic element 110. Although the free layer 120″ is depicted as being simple, the free layer 120″ could have another structure, including two sublayers and an optional nonmagnetic spacer layer as described above. Thus, the magnetic element 110″ has the advantages of the magnetic element 110.

The magnetic element 110″ is deposited on the substrate in a different order than the magnetic elements 110 and 110′. In particular, the free layer 120″ is closer to the bottom contact 112″ and, therefore, to the substrate (not shown, but would be located below layers depicted) than the pinned layer 116″. Consequently, a seed layer 134 is used between the free layer 120″ and the bottom contact 112″. The seed layer is selected to promote the desired crystal structure and texture of the free layer 120″. In particular, materials for the seed layer 134 are selected to promote a bcc crystal structure and a (100) texture of the free layer 120″. In particular, the seed layer 134 preferably includes Cr, Ta, TaN, TiN, or TaN/Ta. Note that if a single layer is used for the free layer 120″, in lieu of layers corresponding to layers 122, 124 and 126, the free layer 120″ preferably includes at least one of Co, Fe, and Ni that are configured to have a bcc crystal structure with a (100) texture.

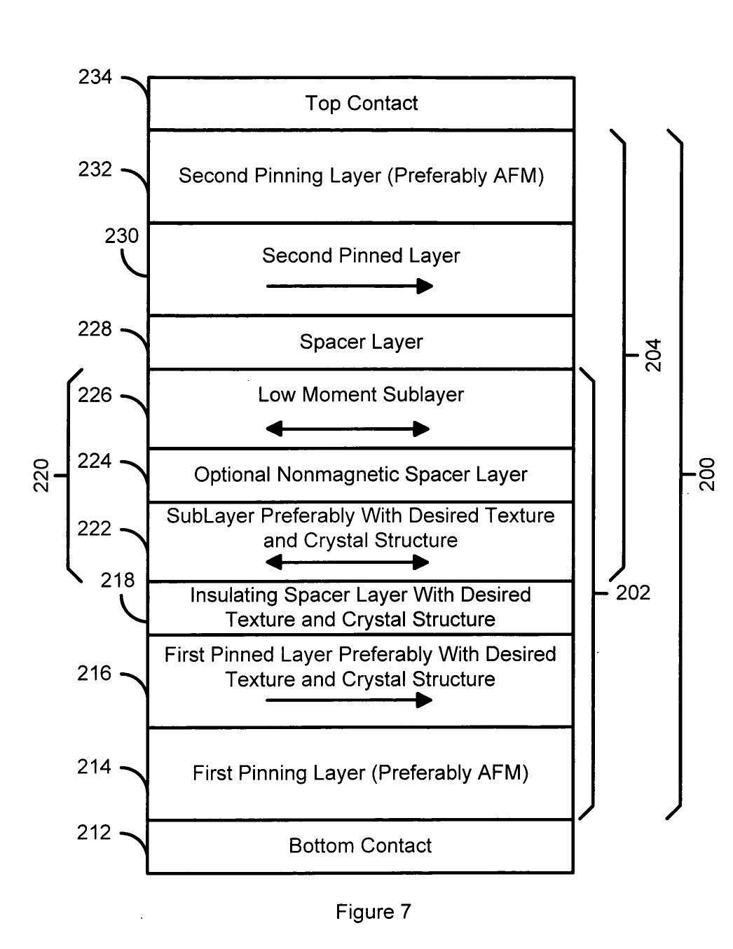

FIG. 7 is a diagram of a second embodiment of a magnetic element 200 in accordance with the present invention and which can be written using spin transfer. The magnetic element 200 is a dual spin filter. The magnetic element 200 includes a first pinned layer 216, an insulating spacer layer 218, a free layer 220, a spacer layer 228, and a second pinned layer 230. The spacer layer 228 is nonmagnetic and either conductive or another insulating tunneling barrier. The magnetic element 200 also preferably includes a first pinning layer 214 and a second pinning layer 232. Also depicted are a bottom contact 212 and a top contact 234. Thus in case of a conducting spacer layer 228, the magnetic element 200 could be considered to include a spin tunneling junction 202 and a spin valve 204 that share a free layer 220. However in case of an insulating tunneling barrier for the spacer layer 228, the magnetic element 200 could be considered to include two spin tunneling junction, 202 and 204, that share a free layer 220. Furthermore, although the magnetic element 200 is depicted with layers having a particular orientation to the substrate (not shown). In particular, the first pinned layer 216 is depicted as being in proximity to the substrate, below the free layer 220. However, another orientation could be used.

The bottom contact 212 and the top contact 234 are used to drive current through the magnetic element 200 in a CPP direction. The pinning layers 214 and 232 are preferably AFM layers. The AFM layer 214 has an ordered crystal structure and, preferably, a particular texture. In addition, seed layers (not shown) may be used to provide a desired texture of the AFM layer 214. For example, if IrMn is used for the AFM layer 214, a Ta(N) underlayer, which is a mixture of β-Ta and TaN, is used to ensure that the IrMn AFM layer 214 is face centered cubic (fcc) having a (002) texture. The AFM layer 214 preferably pins the magnetization of the first pinned layer 216 through exchange coupling.

The first pinned layer 216 has its magnetization pinned by the pinning layer 214. The portion of the pinned layer 216 adjacent to the insulating spacer layer 218, has a texture. In a preferred embodiment, this texture is (100) for a body centered cubic (bcc) crystal structure. Moreover, although depicted as a simple layer, the pinned layer 216 may have another structure. For example, the pinned layer 216 may be a bilayer. In such an embodiment, the layer of the pinned layer 216 that is adjacent to the AFM layer 214 is preferably configured to improve the ability of the AFM layer 214 to pin the magnetization of the pinned layer 216. The other bilayer would be configured to have the texture described above. The pinned layer 216 may be a synthetic pinned layer including two ferromagnetic layers separated by a nonmagnetic spacer layer. The thickness of the nonmagnetic spacer layer is configured so that the magnetizations of the ferromagnetic layers are antiferromagnetically coupled.

The insulating spacer layer 218 corresponds to the spacer layers 104, 118, 118′, and 118″ depicted in FIGS. 3, 4, 5, and 6. Thus, the spacer layer 218 also has an ordered crystal structure. Stated differently, the spacer layer 218 is not amorphous. The spacer layer also preferably has a texture. In a preferred embodiment, there is a well defined relationship between the texture of the pinned layer 216, or the sublayer of the pinned layer 216 that is adjacent to the spacer layer 218, and the texture of the spacer layer 218. Also in a preferred embodiment, the spacer layer 218 includes at least ten atomic percent Mg and has a rock salt (NaCl) structure. Thus, the spacer layer 218 is preferably MgO. The spacer layer 218 is also configured to allow tunneling through the spacer layer 218. In a preferred embodiment, the texture of the spacer layer 218 is (100).

Although the free layer 220 may be simple, the free layer 220 preferably includes a first sublayer 222, an optional nonmagnetic spacer layer 224, and a second sublayer 226. The sublayers 222 and 226 are ferromagnetic. The first sublayer 222, or the portion of the free layer 220 adjacent to the spacer layer 218, preferably has a bcc crystal structure and a (100) texture. Also in a preferred embodiment, the first sublayer 222 is a metallic alloy including at least one of Co, Fe, Ni, Cr, and Mn, or an amorphous alloy including at least one of Co, Fe, Ni, and Cr, with at least one of B, P, Si, Nb, Zr, Hf, Ta, Ti. The second sublayer 226 would preferably have a reduced magnetic moment. A reduced magnetic moment is preferably a magnetic moment of less than or equal to 1100 emu/cm³. In one embodiment, the second sublayer 226 is amorphous, contains more than ten atomic percent of boron, and includes at least one of Co, Fe, Ni, Cr, and Mn. In either case, the sublayers 222 and 226 include Co, Fe or Ni. The magnetizations of the sublayers 222 and 226 are closely coupled such that the relative orientation of the magnetizations of the sublayers 222 and 226 is constant. For example, the magnetizations would remain antiparallel or parallel due to this coupling. The free layer 220 might also include an optional nonmagnetic spacer layer 224 between the sublayers 222 and 226. The optional nonmagnetic spacer layer 224 is preferably configured to exchange couple the magnetizations of the sublayers 222 and 226. In addition, the optional nonmagnetic spacer layer 224 may act as a diffusion stop layer.

The magnetic element 200 is also configured to allow the free layer 220 to be switched due to spin transfer when a write current is passed through the magnetic element 200. In a preferred embodiment, the lateral dimensions, such as the width w, of the free layer 220 are thus small and preferably less than two hundred nanometers. In addition, some difference is preferably provided between the lateral dimensions to ensure that the free layer 220 has a particular easy axis.

The magnetic element 200 can be written using spin transfer. Further, because of the crystal structure of the spacer layer 218 and the relationship between the textures of the spacer layer 218 and the pinned layer 216, well defined electronic states dominate the tunneling process through the spacer layer 218. This is further improved by the texture of the sublayer 222 of the free layer 220. Consequently, the signal from the magnetic element 200 may be increased. Because of the improved spin polarization through the spacer layer 218, the critical current required to switch the magnetization of the free layer 220 might be reduced. Moreover, the pinned layers 216 and 230 can be configured such that the spin transfer torques from the pinned layers 216 and 230 are additive when writing to the magnetic element. This further reduces the critical current required to switch the magnetization of the free layer 220. Thus, the magnetic element 200 may be more readily used in higher density magnetic memories.

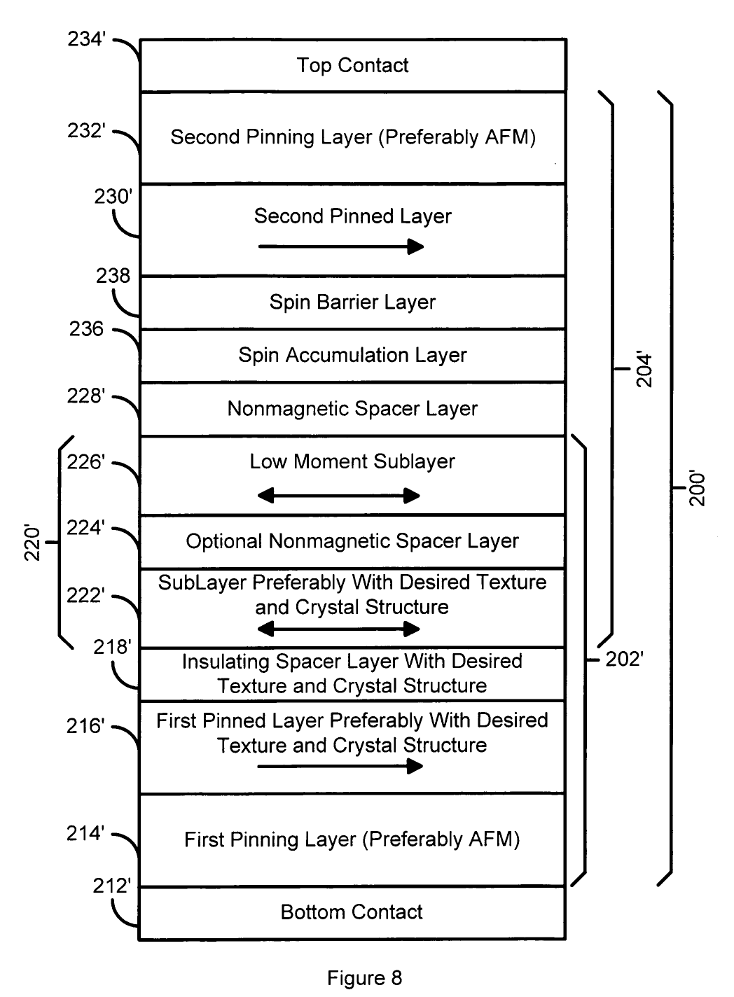

FIG. 8 is a diagram of a second version of the second embodiment of a magnetic element 200′ in accordance with the present invention and which can be written using spin transfer. The magnetic element 200′ is analogous to the magnetic element 200. Consequently, analogous portions of the magnetic element 200′ are labeled similarly. For example, the magnetic element 200′ includes a first pinned layer 216′, insulating spacer layer 218′, free layer 220′, second spacer layer 228′, and second pinned layer 230′ that are analogous to the layers 216, 218, 220, 228, and 230 of the magnetic element 200. Thus, the magnetic element 200′ has the advantages of the magnetic element 200.

In addition, the magnetic element 200′ includes a spin accumulation layer 236 and spin barrier layer 238. The spin barrier layer 238 is configured to provide specular reflections of electrons, which improves the ability of the free layer 220′ to be switched using spin transfer. For example, the spin barrier layer preferably is a poor tunneling barrier having a low RA product, less than ten percent of the value of the RA of the total magnetic element 200′.

The spin accumulation layer 236 is a nonmagnetic layer that preferably has a long spin diffusion length. Thus, the spin accumulation layer 236 preferably includes materials such as Cu and Ru. The spin accumulation layer 236 and the spin barrier layer 238 are used to improve the spin transfer effect's ability to switch the magnetization of the free layer 220′ by reducing damping resulting from the spin pumping effect. This damping is reduced because the spin accumulation layer 236 and the spin barrier layer 238 can work to reflect spin polarized current back towards the free layer 220′. Thus, the magnetic element 200′ can be more easily switched, at a lower write current.

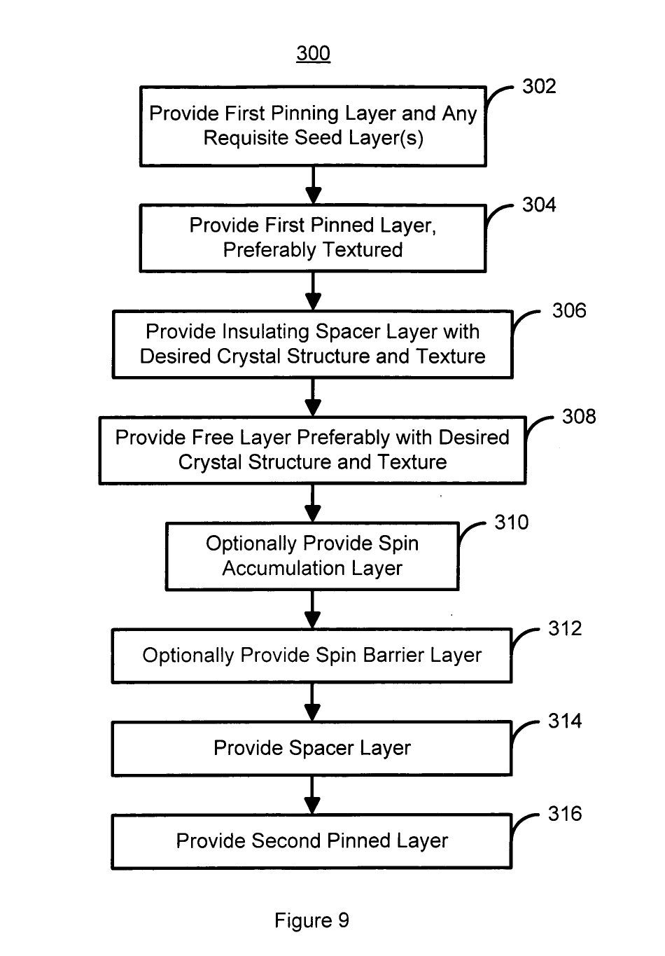

FIG. 9 is a diagram depicting one embodiment of a method 300 in accordance with the present invention for providing magnetic element in accordance which can be written using spin transfer. The method 300 is described in the context of the magnetic element 200′. However, nothing prevents the use of the method 300 with other magnetic elements. The method 300 is also described in the context of providing a single magnetic element. However, one of ordinary skill in the art will readily recognize that multiple elements may be provided. The method 300 preferably commences with deposition of the first pinning layer 214′ and any requisite seed layer after the bottom contact 212′ is provided, via step 302. The first pinned layer 216′ is provided, via step 304. Step 304 preferably includes providing the first pinned layer 216′ having the desired crystal structure and texture. The insulating spacer layer 218′ is provided, via step 306. Step 306 includes providing the insulating layer 218′ having the desired crystal structure and texture. Step 306 also includes providing the insulating spacer layer 218′ such that tunneling through the insulating spacer layer 218′ between the pinned layer 216′ and free layer 220′.

The free layer 220′ is provided, via step 308. In a preferred embodiment, step 308 includes providing the free layer 220′ with the desired crystal structure and orientation. Step 308 also preferably includes providing the sublayers 222′ and 226′, as well as optionally providing the nonmagnetic spacer layer 224′. Thus the insulating spacer layer 218′ residing between the pinned layer 216′ and the free layer 220′. If the method 300 is used to provide the magnetic element 100 or 110, the remaining steps may be skipped. A spin accumulation layer 236 and spin barrier layer 238 are optionally provide, via steps 310 and 312, respectively. If the method 300 is used to provide the magnetic element 110, the remaining steps may be skipped. Another spacer layer 228′ is provided, via step 314. The spacer layer 228′ is nonmagnetic and can be either conductive or another insulating tunneling barrier. The free layer 220′ thus resides between the insulating spacer layer 218′ and the spacer layer 228′. The second pinned layer 230′ is provided, via step 316. Thus, the spacer layer 228′ resides between the free layer 220′ and the second pinned layer. The second AFM layer 232′ and top contact 234′ may also be provided.

Thus, the magnetic element 100, 110, 110′, 200, and 200′ may be fabricated. Consequently, using the method 300, a magnetic element 100, 110, 110′, 200, and 200′ that can be written using spin transfer, that may have a higher signal and a reduced critical current for writing using spin transfer may be fabricated.

A method and system for providing a magnetic element capable of being written using spin transfer has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We claim:

1. A magnetic element comprising:
a pinned layer;
a spacer layer, the spacer layer being insulating and having an ordered crystal structure, the spacer layer being configured to allow tunneling through the spacer layer;
a free layer, the spacer layer residing between the pinned layer and the free layer; and
wherein the magnetic element is configured to allow the free layer to be switched due to spin transfer when a write current is passed through the magnetic element.

2. The magnetic element of claim 1 wherein the pinned layer has a first crystallographic texture and the spacer layer has a second crystallographic texture.

3. The magnetic element of claim 2 wherein the first crystallographic texture and the second crystallographic texture are related to each other and all (100) oriented.

4. The magnetic element of claim 2 wherein at least a portion of the free layer has a third crystallographic texture.

5. The magnetic element of claim 4 wherein the first crystallographic texture, the second crystallographic texture, and the third crystallographic texture are related to one and another, and all (100) oriented.

6. The magnetic element of claim 1 wherein the free layer includes a single layer having a second ordered crystal structure, or a first sublayer having a first magnetization and a second sublayer having a second magnetization, the first sublayer residing between the spacer layer and the second sublayer, the first sublayer having a second ordered crystal structure, the first magnetization and the second magnetization being coupled.

7. The magnetic element of claim 6 wherein the single free layer or the first sublayer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

8. The magnetic element of claim 1 wherein the pinned layer includes a single layer having a first ordered crystal structure, or synthetic layers with first sublayer having a first magnetization and a second sublayer having a second magnetization, the second sublayer residing adjacent to the spacer layer, the second sublayer having a first ordered crystal structure, the first magnetization and the second magnetization being coupled.

9. The magnetic element of claim 8 wherein the single pinned layer or the second sublayer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

10. The magnetic element of claim 6 wherein the second sublayer is of the form MX, where M includes at least one of Co, Fe, Ni, Cr and Mn and X includes at least one of B, Ta, Pd, Pt or Cr.

11. The magnetic element of claim 6 wherein the first sublayer has a first crystallographic texture, wherein the spacer layer has a second crystallographic texture and wherein the first crystallographic texture and the second crystallographic texture are related to each other and all (100) oriented.

12. The magnetic element of claim 6 wherein the second sublayer has a low magnetization.

13. The magnetic element of claim 12 wherein the low magnetization is less than or equal to 1100 emu/cubic centimeter.

14. The magnetic element of claim 1 wherein the pinned layer is a synthetic pinned layer including a first ferromagnetic layer, a second ferromagnetic, and a nonmagnetic spacer layer configured to magnetically couple the first ferromagnetic layer and the second ferromagnetic layer.

15. The magnetic element of claim 1 wherein the pinned layer includes a first ferromagnetic layer and a second ferromagnetic layer, the second ferromagnetic layer having a texture and residing between the first layer and the spacer layer.

16. The magnetic element of claim 15 wherein the pinned layer further includes a nonmagnetic spacer layer between the first ferromagnetic layer and the second ferromagnetic layer, the nonmagnetic spacer layer including at least one of Ir, Ru, Rh, and Cu.

17. A magnetic element comprising:
a pinned layer;
a spacer layer, the spacer layer being insulating and having a first ordered crystal structure, the spacer layer being configured to allow tunneling through the spacer layer;
a free layer, the spacer layer residing between the pinned layer and the free layer, the free layer includes a first sublayer having a first magnetization and a second sublayer having a second magnetization and a reduced magnetic moment, the first sublayer residing between the spacer layer and the second sublayer, the first sublayer having a second ordered crystal structure, the first magnetization and the second magnetization being coupled; and
wherein the magnetic element is configured to allow the free layer to be switched due to spin transfer when a write current is passed through the magnetic element.

18. The magnetic element of claim 17 wherein the pinned layer has a first texture, the spacer layer has a second texture, and the free layer has a third texture, the first texture, the second texture, and the third texture being related to one and another and all (100) oriented.

19. The magnetic element of claim 17 wherein the first sublayer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

20. The magnetic element of claim 17 wherein the pinned layer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

21. The magnetic element of claim 17 wherein the second sublayer is of the form MX, where M includes at least one of Co, Fe, Ni, Cr and Mn and X includes at least one of B, Ta, Pd, Pt or Cr.

22. The magnetic element of claim 17 wherein the low magnetization is less than or equal to 1100 emu/cubic centimeter.

23. The magnetic element of claim 17 wherein the pinned layer is a synthetic pinned layer including a first ferromagnetic layer, a second ferromagnetic, and a nonmagnetic spacer layer configured to magnetically couple the first ferromagnetic layer and the second ferromagnetic layer.

24. The magnetic element of claim 23 wherein the pinned layer further includes a nonmagnetic spacer layer between the first ferromagnetic layer and the second ferromagnetic layer, the nonmagnetic spacer layer including at least one of Ir, Ru, Rh, and Cu.

25. The magnetic element of claim 17 wherein the spacer layer includes at least ten atomic percent Mg.

26. The magnetic element of claim 25 wherein the spacer layer is MgO.

27. The magnetic element of claim 17 wherein the pinned layer has a body centered cubic structure, the first ordered crystal structure is an NaCl structure, and the second ordered crystal structure is body centered cubic.

28. The magnetic element of claim 17 wherein the second sublayer is amorphous.

29. The magnetic element of claim 17 wherein the free layer further includes a nonmagnetic spacer layer between the first sublayer and the second sublayer.

30. The magnetic element of claim 17 further comprising:
a spin accumulation layer, the free layer residing between the spacer layer and the spin accumulation layer.

31. The magnetic element of claim 30 wherein the spin accumulation layer includes at least one of Cu and Ru.

32. The magnetic element of claim 30 further comprising:
a spin barrier layer, the spin accumulation layer residing between the free layer and the spin barrier layer.

33. The magnetic element of claim 17 wherein the free layer is closer to a substrate than the pinned layer.

34. The magnetic element of claim 17 wherein the pinned layer is closer to a substrate than the free layer.

35. A magnetic element comprising:
a first pinned layer;
an insulating spacer layer, the insulating spacer layer being insulating and having an ordered crystal structure, the insulating spacer layer being configured to allow tunneling through the insulating spacer layer;
a free layer, the insulating spacer layer residing between the pinned layer and the free layer;
a spacer layer, the spacer being nonmagnetic and either a conductive layer or an insulating tunneling layer, the free layer residing between the insulating spacer layer and the spacer layer;
a second pinned layer, the spacer layer residing between the free layer and the second pinned layer; and
wherein the magnetic element is configured to allow the free layer to be switched due to spin transfer when a write current is passed through the magnetic element.

36. A magnetic element comprising:
a first pinned layer;
an insulating spacer layer, the insulating spacer layer being insulating and having a first ordered crystal structure and a second texture, the insulating spacer layer being configured to allow tunneling through the insulating spacer layer;
a free layer, the insulating spacer layer residing between the pinned layer and the free layer, the free layer includes a first sublayer having a first magnetization and a second sublayer having a second magnetization, the first sublayer residing between the insulating spacer layer and the second sublayer, the first sublayer having a second ordered crystal structure with a third texture, the first magnetization and the second magnetization being coupled;
a spacer layer, the spacer being nonmagnetic and either conductive or insulating tunneling layer, the free layer residing between the insulating spacer layer and the spacer layer;
a second pinned layer, the spacer layer residing between the free layer and the second pinned layer;
wherein the magnetic element is configured to allow the free layer to be switched due to spin transfer when a write current is passed through the magnetic element.

37. The magnetic element of claim 36 wherein the first pinned layer has a first texture, the insulating spacer layer has a second texture, and the free layer has a third texture, the first texture, the second texture, and the third texture having a particular crystallographic orientation relationship.

38. The magnetic element of claim 36 wherein the first sublayer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

39. The magnetic element of claim 36 wherein the first pinned layer includes at least one of Co, Fe, Ni, Cr, and Mn, or an amorphous alloy including at least one of Co, Fe, Ni, and Cr, with at least one of B, P, Si, Nb, Zr, Hf, Ta, Ti.

40. The magnetic element of claim 36 wherein the second sublayer has a low magnetic moment.

41. The magnetic element of claim 36 wherein the second sublayer is of the form MX, where M includes at least one of Co, Fe, Ni Cr and Mn and X includes at least one of B, Ta, Pd, Pt or Cr

42. The magnetic element of claim 40 wherein the low magnetic moment is less than or equal to 1100 emu/cubic centimeter.

43. The magnetic element of claim 36 wherein at least one of the first pinned layer and the second pinned layer is a synthetic pinned layer including a first ferromagnetic layer, a second ferromagnetic, and a nonmagnetic spacer layer configured to magnetically couple the first ferromagnetic layer and the second ferromagnetic layer.

44. The magnetic element of claim 36 wherein the insulating spacer layer includes at least ten atomic percent Mg.

45. The magnetic element of claim 44 wherein the insulating spacer layer is MgO.

46. The magnetic element of claim 36 wherein the first pinned layer has a body centered cubic structure, the first ordered crystal structure is an NaCl structure, and the second ordered crystal structure is body centered cubic.

47. The magnetic element of claim 36 wherein the second sublayer is amorphous.

48. The magnetic element of claim 36 wherein the free layer further includes a nonmagnetic spacer layer between the first sublayer and the second sublayer.

49. The magnetic element of claim 36 further comprising:
a spin accumulation layer, the spin accumulation layer residing between the spacer layer and the second pinned layer.

50. The magnetic element of claim 49 wherein the spin accumulation layer includes at least one of Cu and Ru.

51. The magnetic element of claim 49 further comprising:
a spin barrier layer, the spin barrier layer residing between the spin accumulation layer and the second pinned layer.

52. The magnetic element of claim 36 wherein the free layer is closer to a substrate than the first pinned layer.

53. The magnetic element of claim 36 wherein the first pinned layer is closer to a substrate than the free layer.

54. The magnetic element of claim 36 wherein the pinned layer includes a first layer and a second layer, the second layer residing between the first layer and the spacer layer.

55. A method for providing a magnetic element comprising:
providing a pinned layer;
providing a spacer layer, the spacer layer being insulating and having an ordered crystal structure, the spacer layer being configured to allow tunneling through the spacer layer;
providing a free layer, the spacer layer residing between the pinned layer and the free layer; and
wherein the magnetic element is configured to allow the free layer to be switched due to spin transfer when a write current is passed through the magnetic element.

56. The method of claim 55 wherein the free layer providing step further includes:
providing a first sublayer having a first magnetization; and
providing a second sublayer having a second magnetization, the first sublayer residing between the spacer layer and the second sublayer, the first sublayer having a second ordered crystal structure, the first magnetization and the second magnetization being coupled.

57. The method of claim 56 wherein the first sublayer has a first crystallographic texture and wherein the spacer layer has a second crystallographic texture, the first crystallographic texture and the second crystallographic texture are related to each other and all (100) oriented.

58. The method of claim 55 wherein the pinned layer is a synthetic pinned layer including a first ferromagnetic layer, a second ferromagnetic, and a nonmagnetic spacer layer configured to magnetically couple the first ferromagnetic layer and the second ferromagnetic layer.

59. A method for providing magnetic element comprising:
providing a first pinned layer;
providing an insulating spacer layer, the insulating spacer layer being insulating and having an ordered crystal structure, the insulating spacer layer being configured to allow tunneling through the insulating spacer layer;
providing a free layer, the insulating spacer layer residing between the pinned layer and the free layer;
providing a spacer layer, the spacer being nonmagnetic and either conductive or insulating, the free layer residing between the insulating spacer layer and the spacer layer; and
providing a second pinned layer, the spacer layer residing between the free layer and the second pinned layer;
wherein the magnetic element is configured to allow the free layer to be switched due to spin transfer when a write current is passed through the magnetic element.
